(19) United States
(12) Patent Application Publication
(10) Pub. No.: US 2024/0147815 A1
(43) Pub. Date: May 2, 2024

(54) DISPLAY APPARATUS WITH IMPROVED ADHESION CHARACTERISTICS IN NON-ACTIVE AREA

(71) Applicant: LG DISPLAY CO., LTD., SEOUL (KR)

(72) Inventors: Jongmoo HA, Gimpo-si (KR); Geonwoo LEE, Anyang-si (KR)

(73) Assignee: LG DISPLAY CO., LTD., SEOUL (KR)

(21) Appl. No.: 18/384,687

(22) Filed: Oct. 27, 2023

(30) Foreign Application Priority Data
Oct. 28, 2022 (KR) 10-2022-0141235

(51) Int. Cl. H10K 59/80; H10K 59/131; H10K 59/40

(52) U.S. Cl. CPC H10K 59/873; H10K 59/131; H10K 59/40

(57) ABSTRACT

In one aspect, a display apparatus includes a display substrate including an active area configured to display an image and a non-active area enclosing the active area; a thin film transistor on the display substrate that includes a semiconductor layer, a gate electrode, a source electrode, and a drain electrode; a light emitting diode on the thin film transistor of the active area that includes a first electrode, an emission layer, and a second electrode; an encapsulation unit on the light emitting diode; a touch sensor on the encapsulation unit that includes a plurality of touch electrodes; a touch protection layer configured to cover the touch sensor; a dam on the encapsulation unit; a crack detection unit configured to detect at least one crack in the display apparatus; and a data line configured to supply common voltage to the light emitting diode.

### CROSS-REFERENCE TO RELATED APPLICATIONS

This application claims the priority of Korean Patent Application No. 10-2022-0141235 filed on Oct. 28, 2022, in the Korean Intellectual Property Office, the entire disclosure of which is incorporated herein by reference.

### BACKGROUND

### Field of Disclosure

The present disclosure relates to a display apparatus, and more particularly, to a display apparatus in which a plurality of partition walls is formed in a non-active area and an adhesive force to the plurality of partition walls is improved.

### Description of the Background

Various types and forms of display apparatuses are being used as TVs, monitors, smart phones, tablet PCs, notebooks, etc.

Among various types of display apparatus, a liquid crystal display (LCD) device has been widely adopted up to this point. However, adoption of organic light emitting display (OLED) devices are is on the rise.

Display apparatuses include display panels having a plurality of light emitting diodes or liquid crystal for implementing images and thin film transistors which individually control operations of light emitting diodes and liquid crystals.

Among them, the liquid crystal display device is not a self-emitting device, hence, a light source such as a backlight which supplies light from a rear surface is required. The backlight increases a thickness of the liquid crystal display device and induces restrictions on implementing a display apparatus which is bendable or otherwise has alternate and uncommon types of designs.

The organic light emitting display apparatus having a light emitting diode may be implemented to be thinner than a display apparatus with a light source therein and hence, does not require a separate light source. This renders organic light emitting display apparatuses suitable for implementation as a display apparatus which is bendable or otherwise has alternate or uncommon designs.

To drive the light emitting diode of the organic light emitting display apparatus, a thin film transistor is disposed in the display apparatus and a voltage is applied to the light emitting diode to drive the organic light emitting display apparatus.

### SUMMARY

When moisture or external foreign materials permeate the light emitting diode of the display apparatus, the light emitting diode is easily damaged so as not to be driven, so that an encapsulation unit which suppresses the permeation of moisture or external foreign materials may be further disposed in the light emitting diode.

The encapsulation unit is formed of a transparent material to allow light emitted from the light emitting diode to be easily transmitted. The encapsulation unit is formed to be thick to planarize a step there below so that an end area of the encapsulation unit has a high slope downwardly slanted. Light emitted from the light emitting diode is refracted by an end slope area of the encapsulation unit so that a display quality of an image which is visible from a side part of the display panel may be degraded.

A cover layer may be formed to minimize a refractive index of light emitted from a side area of the display panel and to protect the display panel. When the cover layer flows to the outside of the display apparatus during the process of forming the cover layer, the display apparatus may be contaminated or a flatness of a surface of the cover layer may be lowered.

According to the present disclosure, a plurality of partition walls which suppresses the flowing of the cover layer to the outside of the display apparatus and makes the slope of the surface of the cover layer gentle, may be formed.

The plurality of partition walls may be detached to be separated during the process of forming a cover layer or a cleaning process, and to suppress this problem, a partition wall fixing unit is formed or the plurality of partition walls is brought into contact with a layer formed of an organic material to improve the adhesive force.

Objects of the present disclosure are not limited to the above-mentioned objects, and other objects, which are not mentioned above, may be clearly understood by those skilled in the art from the following descriptions.

In one aspect, a display apparatus includes a display substrate including an active area configured to display an image and a non-active area enclosing the active area; a thin film transistor on the display substrate that includes a semiconductor layer, a gate electrode, a source electrode, and a drain electrode; a light emitting diode on the thin film transistor of the active area that includes a first electrode, an emission layer, and a second electrode; an encapsulation unit on the light emitting diode; a touch sensor on the encapsulation unit that includes a plurality of touch electrodes; a touch protection layer configured to cover the touch sensor; a dam on the encapsulation unit; a crack detection unit configured to detect at least one crack in the display apparatus; and a data line configured to supply common voltage to the light emitting diode.

In another aspect, the display apparatus further includes an organic layer in the non-active area configured to prevent the at least one crack in the display apparatus.

In another aspect, the dam, the crack detection unit, and the data line are on the same layer.

In another aspect, the organic layer is between the dam and the crack detection unit.

In another aspect, the display apparatus further includes a first common line; a second common line; and a connection line, wherein the data line is configured to supply the common voltage to the connection line.

In another aspect, the first common line, the second common line, and the connection line are connected to the dam.

In another aspect, the first common line, the second common line, and the connection line are in the same layer as the data line.

In another aspect, the display apparatus further includes a plurality of partition walls in the non-active area configured with the same material as the touch protection layer.

In another aspect, the display apparatus further includes a partition wall fixing unit configured with the same material as the plurality of touch electrodes and configured to be in contact with bottom surfaces of the plurality of partition walls.

In another aspect, the plurality of partition walls is configured to cover a top surface and a side surface of the partition wall fixing unit.

In another aspect, the partition wall fixing unit is configured to be in contact with bottom surfaces and a part of side surfaces of the plurality of partition walls.

In another aspect, the display apparatus further includes a cover layer on the touch protection layer and the plurality of partition walls.

In another aspect, a refractive index of the cover layer is higher than a refractive index of the touch protection layer.

In another aspect, the plurality of touch electrodes includes a lower touch electrode and an upper touch electrode, the touch sensor further includes a touch insulating film between the lower touch electrode and the upper touch electrode, the touch insulating film extends to the non-active area, and a plurality of opening areas in which the touch insulating film is not disposed in an area overlapping the plurality of partition walls is included.

In another aspect, a first touch insulating film portion is between the plurality of opening areas and a partition wall fixing unit is on the first touch insulating film portion.

In another aspect, the plurality of touch electrodes includes a lower touch electrode and an upper touch electrode, the touch sensor further includes a touch insulating film between the lower touch electrode and the upper touch electrode, the touch insulating film extends to the non-active area, and the touch insulating film is not disposed in an area overlapping the plurality of partition walls.

In another aspect, the display apparatus further includes a bank layer on the same layer as the emission layer, wherein the bank layer extends to the non-active area, and the plurality of partition walls is in contact with the bank layer.

In another aspect, the display apparatus further includes a first planarization layer and a second planarization layer between the thin film transistor and the light emitting diode, wherein the first planarization layer and the second planarization layer extend to the non-active area, and the plurality of partition walls is in contact with one of the first planarization layer and the second planarization layer.

In one aspect, a display apparatus includes a display substrate including an active area configured to display an image and a non-active area enclosing the active area; an organic layer in the non-active area configured to prevent a crack in the display apparatus; and a crack detection unit configured to detect at least one crack in the display apparatus.

In another aspect, the display apparatus further includes a light emitting diode in the active area; an encapsulation layer on the light emitting diode; and a dam on the encapsulation layer.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1A is a plan view of a front surface of a display apparatus according to an exemplary aspect of the present disclosure;

FIG. 1B is a plan view of a rear surface of a display apparatus according to an exemplary aspect of the present disclosure;

FIG. 2 is a cross-sectional view taken along a line A-A′ of FIG. 1A according to an exemplary aspect of the present disclosure;

FIG. 3 is a view illustrating a touch sensor according to an exemplary aspect of the present disclosure;

FIG. 4 is a cross-sectional view taken along the line A-A′ of FIG. 1A according to another exemplary aspect of the present disclosure;

FIGS. 5A to 5C are views illustrating another exemplary aspect of a plurality of partition walls of a region B of FIG. 4; and

FIGS. 6A and 6B are views illustrating another exemplary aspect of a plurality of partition walls of a region B of FIG. 4.

### DETAILED DESCRIPTION

Various examples of the present disclosure are discussed in detail below. While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and, such references mean at least one of the embodiments.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly” is not used.

When an element or layer is disposed “on” the other element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure may be partially or entirely bonded to or combined with each other and may be interlocked and operated in technically various ways understood by those skilled in the art, and the embodiments may be carried out independently of or in association with each other.

The display apparatus of the present specification may be applied to a liquid crystal display apparatus and an organic light emitting display apparatus, but is not limited thereto, and may be applied to various display apparatuses such as an LED display apparatus or a quantum dot display apparatus.

Hereinafter, a display apparatus according to an exemplary aspect of the present disclosure will be described with reference to the drawings.

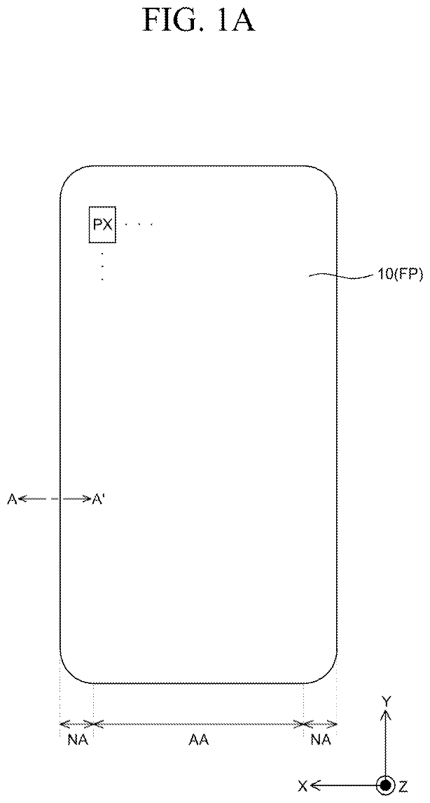

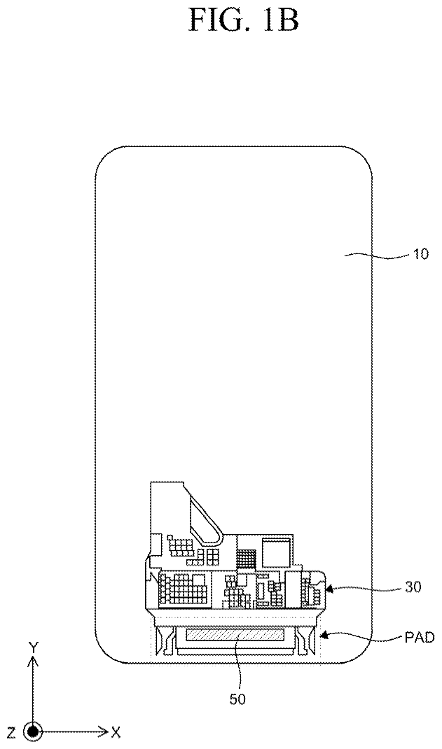

FIG. 1A is a plan view of a front surface of a display apparatus according to an exemplary aspect of the present disclosure.

FIG. 1B is a plan view of a rear surface of a display apparatus according to an exemplary aspect of the present disclosure.

Referring to FIGS. 1A and 1B, a display apparatus may include a display panel 10, a gate driver and a data driver 50 which are connected to the display panel 10 to apply a driving signal and a driving voltage, and a circuit board 30.

The display panel 10 may be divided into an active area AA in which a light emitting diode is included to display images and a non-active area NA in which the gate driver and the data driver 50 are disposed.

The active area AA may be an area where a plurality of sub pixels PX is disposed on a display substrate to display images. Each of the plurality of sub pixels PX is an individual unit which emits light and in each of the plurality of sub pixels PX, a light emitting diode and a thin film transistor may be formed.

The plurality of sub pixels PX may include a red sub pixel, a green sub pixel, a blue sub pixel and/or a white sub pixel, but is not limited thereto.

The non-active area NA may be an area where no image is displayed. In the non-active area NA, various wiring lines and driving ICs for driving a plurality of sub pixels PX disposed in the active area AA may be disposed. For example, in the non-active area NA, a gate driver, a data driver 50, and a circuit board 30 may be disposed.

The non-active area NA may be an area which encloses the active area AA. For example, the non-active area NA may be an area extending from the active area AA or an area in which the plurality of sub pixels PX is not disposed. The non-active area NA in which no image is displayed may be a bezel area.

The plurality of sub pixels PX of the active area AA may include thin film transistors. The thin film transistor in the active area AA may include a polycrystalline semiconductor material and/or an oxide semiconductor material.

The gate driver may apply a gate in panel (GIP) manner in which a gate driving chip is directly mounted on a display substrate or the gate driving circuit is directly formed on the display substrate. According to the GIP manner in which the gate driving circuit is directly formed on the display substrate, a thin film transistor using a polycrystalline material as a semiconductor layer and a thin film transistor using an oxide semiconductor material as a semiconductor layer are configured as C-MOS to be directly formed on the display substrate. By doing this, the electron mobility in a channel in the thin film transistor is increased to implement a display apparatus with a high resolution and low power consumption.

In the active area AA, a plurality of data lines and a plurality of gate lines may be disposed. For example, the plurality of data lines may be disposed in rows or columns, and the plurality of gate lines may be disposed in columns or rows. In the display panel 10, on an area where the plurality of data lines and the plurality gate lines are disposed, the sub pixel PX may be disposed.

The display panel 10 may include a plurality of scan lines and a plurality of emission control lines. The plurality of scan lines and the plurality of emission control lines may be lines which transmit different types of gate signals (a scan signal or an emission control signal) to a gate node of different types of thin film transistors (a switching transistor or a driving transistor).

The gate driver may include a scan driving circuit which outputs scan signals to a plurality of scan lines which is one type of gate line and an emission driving circuit which outputs emission control signals to a plurality of emission control lines which is another type of gate line.

The display panel 10 may include a front portion FP, a bending portion which may extend from the front portion FP to be bendable, and a pad portion PAD which extends from the bending portion and is disposed below the front portion FP.

In the pad portion PAD disposed below the display panel 10, the data driver 50 may be disposed. The data driver 50 receives digital video data and a source control signal from a timing controller. The data driver 50 converts digital video data into analog data voltages according to a source control signal to supply the converted analog data voltages to the data lines. The data driver 50 may be formed as a data driving chip, and may be connected to the display panel 10 by a chip on panel (COP) manner by which the data driver is directly mounted in the pad portion PAD of the display panel 10 or a chip on film (COF) manner by which the data driver is mounted on the circuit board 30.

The gate driver disposed in the non-active area NA sequentially supplies scan signal to the plurality of gate lines to sequentially drive each sub pixel PX rows of the active area AA.

When a specific gate line is open by the gate driver, the data driver 50 converts image data into data voltage in analog form to supply the converted data voltage to the plurality of data lines.

The data line may supply a common voltage and a driving voltage of the data driver 50 to the plurality of sub pixels PX of the active area AA and may be disposed to pass through the bending portion.

An end of the pad portion PAD may be connected to the data driver 50 and the circuit board 30 having the timing controller. The circuit board 30 may be connected to the display panel 10 in a film on panel (FOP) manner. The circuit board 30 may be attached to the pad portion PAD using an anisotropic conducting film and may be electrically connected to the pad portion PAD.

The timing controller receives digital video data and a timing signal from an external system board. The timing controller generates a gate control signal for controlling an operation timing of the gate driver and a data control signal for controlling a data driver based on the timing signal. The timing controller supplies a gate control signal to the gate driver and may supply a data control signal to the data driver 50.

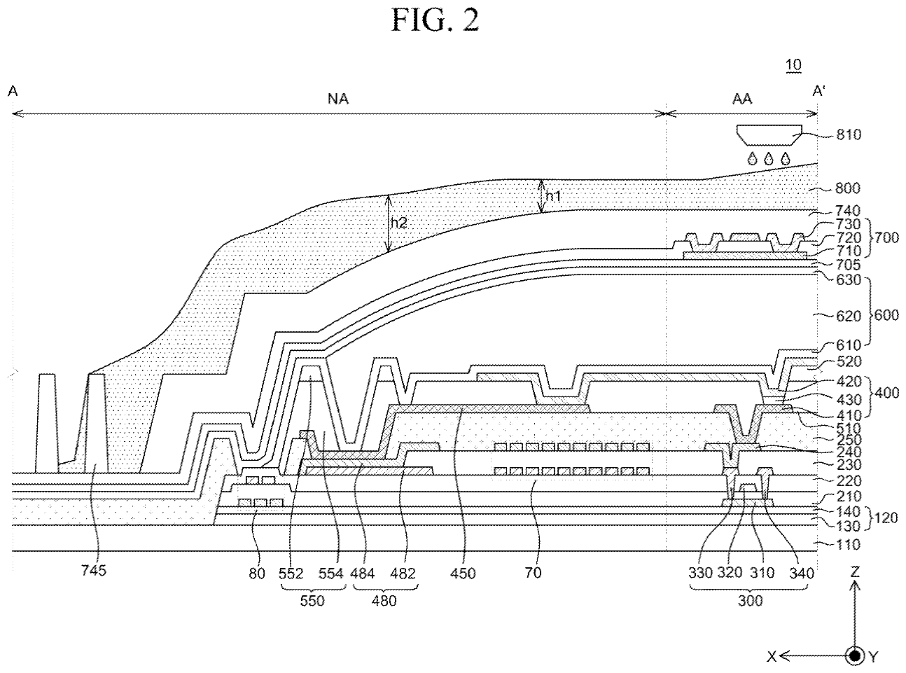

FIG. 2 is a cross-sectional view taken along the line A-A′ of FIG. 1A. FIG. 2 illustrates a left area of the display panel 10 in plain view, but the exemplary aspect of the present disclosure may be applied to the upper, lower, and right areas of the display panel 10 in plain view in the same way.

Referring to FIG. 2, the display substrate 110 disposed below the display panel 10 may be formed of glass or a plastic material. When the display substrate 110 is formed of a plastic material, the display panel 10 may have flexibility.

The display substrate 110 may include an active area AA in which images are displayed and a non-active area NA enclosing the active area AA, similar to the display panel 10.

The display substrate 110 formed of a plastic material may be configured as a multi-layer in which an organic film and an inorganic film are alternately laminated. For example, the display substrate 110 may be configured by alternately laminating an organic film such as polyimide and an inorganic film such as silicon oxide, but the exemplary embodiments of the present disclosure are not limited thereto.

A buffer layer 120 may be disposed on the display substrate 110. The buffer layer 120 may include a lower buffer layer 130 and an upper buffer layer 140.

The lower buffer layer 130 is provided to block moisture which may permeate through the display substrate 110 from the outside, and may be configured as a single layer of a silicon oxide (SiOx) film or a silicon nitride (SiN) film or configured by laminating a plurality of layers thereof.

The upper buffer layer 140 protects the semiconductor layer 310 of the thin film transistor 300 formed there above and provides a base for forming the semiconductor layer 310. The upper buffer layer 140 may block various types of defects introduced from the display substrate 110. The upper buffer layer 140 may be formed to include amorphous silicon (a-Si).

A thin film transistor 300 may be disposed on the buffer layer 120 and specifically, the semiconductor layer 310 of the thin film transistor 300 may be disposed. The thin film transistor 300 includes the semiconductor layer 310, a gate electrode 320, a source electrode 330, and a drain electrode 340 and may supply a driving current to a light emitting diode 400 in accordance with a data voltage applied from the data line. The thin film transistor 300 may include oxide semiconductor or polycrystalline semiconductor as the semiconductor layer 310.

The gate insulating layer 210 and the gate electrode 320 may be disposed on the semiconductor layer 310. The gate insulating layer 210 may be formed of an inorganic insulating material, such as a silicon nitride layer (SiNx), a silicon oxy nitride layer (SiONx), a silicon oxide layer (SiOx), a titanium oxide layer (TiOx), or an aluminum oxide layer (AlOx). The semiconductor layer 310 and the gate electrode 320 may be disposed to be spaced apart from each other while protecting the semiconductor layer 310.

The gate electrode 320 may be disposed on the gate insulating layer 210. The gate electrode 320 is connected to the gate line to be applied with a scan signal supplied from the gate driver. The gate electrode 320 may be formed of a single layer or a plurality of layers formed of any one of molybdenum (Mo), aluminum (Al), chrome (Cr), gold (Au), titanium (Ti), nickel (Ni), neodymium (Nd), and copper (Cu), or an alloy thereof.

In the non-active area NA, a crack detecting unit 80 including the same material as the semiconductor layer 310 and the same material as the gate electrode 320 may be formed. The crack detecting unit 30 may be continuously formed along an outer boundary portion of the display panel 10 to detect a crack generated in the display panel 10.

The interlayer insulating layer 220 may be disposed on the gate electrode 320 of the active area AA. The interlayer insulating layer 220 may be formed of an inorganic film, for example, a silicon nitride layer (SiNx), a silicon oxy nitride layer (SiONx), a silicon oxide layer (SiOx), a titanium oxide layer (TiOx), or an aluminum oxide layer (AlOx). The interlayer insulating layer 220 may be formed to include a plurality of inorganic films.

A source electrode 330 and a drain electrode 340 may be formed on the interlayer insulating layer 220. The source electrode 330 and the drain electrode 340 may be electrically connected to the semiconductor layer 310 by forming the contact hole in the interlayer insulating layer 220 and/or the gate insulating layer 210.

The source electrode 330 and the drain electrode 340 may be formed of a single layer or a plurality of layers formed of any one of molybdenum (Mo), aluminum (Al), chrome (Cr), gold (Au), titanium (Ti), nickel (Ni), neodymium (Nd), and copper (Cu), or an alloy thereof.

Functions of the source electrode 330 and the drain electrode 340 may be switched depending on a configuring material and thus the terms may also be switched. The source electrode 330 or the drain electrode 340 is connected to the data line to input a data voltage or signal thereto, and may supply a predetermined current or voltage to the first electrode 410 of the light emitting diode 400.

A first planarization layer 230 and/or a second planarization layer 250 may be formed on the thin film transistor 300 to planarize step differences caused by the thickness difference of various components. When the first planarization layer 230 and/or the second planarization layer 250 are formed, the distance between the light emitting diode 400 and the thin film transistor (or a signal line) may be increased and the influence of the noise generated in the thin film transistor (or the signal line) on the light emitting diode 400 may be reduced.

The first planarization layer 230 and/or the second planarization layer 250 may be formed on the entire active area AA and non-active area NA. Alternatively, the first planarization layer 230 and/or the second planarization layer 250 may not be formed in a part of an end of the non-active area NA which is not required to be planarized.

The first planarization layer 230 and the second planarization layer 250 may be configured by an organic material such as acrylic, polyimide based, or siloxane-based resin, but the exemplary embodiments of the present disclosure are not limited thereto.

The light emitting diode 400 is formed on the second planarization layer 250. The light emitting diode 400 may include a first electrode 410 (or an anode electrode), a second electrode 420 (or a cathode electrode) corresponding to the first electrode 410, and an emission layer 430 located between the first electrode 410 and the second electrode 420. The first electrode 410 and the emission layer 430 may be formed in every sub pixel PX and the second electrode 420 may be formed in the entire area of the active area AA.

The light emitting diode 400 may be connected to the source electrode 330 or the drain electrode 340 of the thin film transistor 300 through the connection electrode 240 formed on the first planarization layer 230. The thin film transistor 300 and the light emitting diode 400 may be connected through the connection electrode 240.

The connection electrode 240 may be formed of a single layer or a plurality of layers formed of any one of molybdenum (Mo), aluminum (Al), chrome (Cr), gold (Au), titanium (Ti), nickel (Ni), neodymium (Nd), and copper (Cu), or an alloy thereof.

The first electrode 410 is connected to the connection electrode 240 through a contact hole which passes through the second planarization layer 250, and the connection electrode 240 may be connected to the source electrode 330 or the drain electrode 340 through a contact hole which passes through the first planarization layer 230.

A data voltage (current) or signal may be input to the first electrode 410 through the thin film transistor 300, and a common voltage EVSS which is a low potential voltage may be applied to the second electrode 420.

When a voltage is applied to the first electrode 410 and the second electrode 420, each of holes and electrons are coupled in the emission layer to emit light.

To apply a common voltage to the second electrode 420, the second electrode 420 may be connected to the connection line 450 and the common line 480. The common line 480 is connected to the data driver 70 or the circuit board 30 to supply a common voltage (or a negative or ground) to the connection line 450, and the connection line 450 is connected to the common line 480 and the second electrode 420 to supply the common voltage to the second electrode 420.

Throughout the present disclosure, the data driver 70 may also be referred to as the gate driver 70, a data line 70, a gate line 70, or simply a signal line 70.

The connection line 450 may be separately formed or may be formed by extending the second electrode 420. For example, the connection line 450 includes a metal which is the same material as the first electrode 410 and may be formed on the second planarization layer 250.

The connection line 450 may be formed to have a plurality of layers structure including a transparent conducting layer and/or an opaque conducting layer having a high reflection efficiency. The transparent conducting layer is formed of a material having a relatively high work function, such as indium-tin-oxide (ITO) or indium-zinc-oxide (IZO), and the opaque conducting layer is formed with a single or a plurality of layers structure including aluminum (Al), silver (Ag), copper (Cu), lead (Pb), molybdenum (Mo), titanium (Ti), or an alloy thereof. However, the exemplary embodiments of the present disclosure are not limited thereto.

The connection line 450 may be connected to the second electrode 420 by forming a contact hole in the bank layer 510 and/or the spacer 520.

In an end area of the connection line 450, a common line 480 which is connected to the connection line 450 to apply a common voltage may be disposed. The common line 480 may include a first common line 482 formed of a metal which is the same material as the source electrode 330. The common line 480 may include a second common line 484 formed of a metal which is the same material as the connection electrode 240. For example, the common line 480 may be formed by laminating the first common line 482 and the second common line 484.

The connection line 450 and the common line 480 may be in contact with each other by forming contact holes in the first planarization layer 230 and/or the second planarization layer 250.

When the gate driver 70 which is disposed in the non-active area NA of the display substrate 110 is applied in a gate in panel (GIP) manner, a gate driving circuit configured by a plurality of thin film transistors may be formed in the non-active area NA.

The gate driving circuit may be formed of the same material as the thin film transistor 300 which drives the light emitting diode 400 and/or the connection electrode 240.

For example, the gate driving circuit may include a metal which is the same material as the source electrode 330 of the thin film transistor 300, and may include a metal which is the same material as the connection electrode 240 which connects the light emitting diode 400 and the thin film transistor 300.

The first electrode 410 disposed in the active area AA may be formed with a plurality of layers structure including a transparent conducting layer or an opaque conducting layer having a high reflection efficiency. The transparent conducting layer is formed of a material having a relatively high work function, such as indium-tin-oxide (ITO) or indium-zinc-oxide (IZO), and the opaque conducting layer may be formed with a single or a plurality of layers structure including aluminum (Al), silver (Ag), copper (Cu), lead (Pb), molybdenum (Mo), titanium (Ti), or an alloy thereof. However, the exemplary embodiments of the present disclosure are not limited thereto.

For example, the first electrode 410 may be formed with a structure in which a transparent conducting layer, an opaque conducting layer, and a transparent conducting layer are sequentially laminated, or a structure in which a transparent conducting layer and an opaque conducting layer are sequentially laminated. However, the exemplary embodiments of the present disclosure are not limited thereto.

The emission layer 430 may be formed by laminating a hole related layer, an organic emission layer, and an electron related layer on the first electrode 410 in this order or in a reverse order.

A bank layer 510 may be formed between emission layers 430. The bank layer 510 is formed on the first electrode 410 of each sub pixel PX and may be a pixel definition film which exposes the first electrode 410. For example, in the active area AA, the bank layer 510 may be disposed on the first electrode 410 and may be disposed to cover a part of the first electrode 410.

The bank layer 510 may be formed of a transparent material or may be formed of an opaque material to suppress light interference between adjacent sub pixels PX. For example, the bank layer 510 may include a light shielding material formed of any one of a color pigment, an organic black, and carbon.

The bank layer 510 may be formed in the entire active area AA and non-active area NA. The bank layer 510 may not be formed in a partial area of the end of the non-active area NA in which the emission layer 430 and the dam 550 are not formed.

A spacer 520 may be disposed on the bank layer 510. A fine metal mask which is a deposition mask may be used in the non-active area NA of the display substrate 110 to form the emission layer 430. To suppress a damage which may be caused by a contact with the deposition mask disposed on the bank layer 510 and maintain a predetermined distance between the bank layer 510 and the deposition mask, a spacer 520 may be disposed above the bank layer 450. The spacer 520 is configured by one of polyimide (PI), photoacryl (PAC), and benzocyclobutene (BCB) which are transparent organic materials.

A dam 550 may be formed in the non-active area NA of the display panel 110. The dam 550 may be disposed to block the encapsulation unit 600 formed on the second electrode 420 from flowing to the outside of the display panel 10.

The dam 550 may be formed to include one or more of a lower dam layer 554 formed of the same material as the bank layer 510 and an upper dam layer 552 formed of the same material as the spacer 520. For example, the dam 550 is patterned after forming the bank layer 510 and the spacer 520 to have a structure in which the lower dam layer 554 and the upper dam layer 552 are laminated.

The second electrode 420 may be disposed on the bank layer 510, the spacer 520, and the emission layer 430. The second electrode 420 may be formed on a top surface and a side surface of the emission layer 430 to be opposite to the first electrode 410 with the emission layer 430 therebetween.

The second electrode 420 may be integrally formed on the entire surface of the active area AA. When the second electrode 420 is applied to a top-emission type organic light emitting display apparatus, the second electrode may be configured by a transparent conducting layer, such as indium-tin-oxide (ITO) or indium-zinc-oxide (IZO).

An encapsulation unit 600 may be disposed on the second electrode 420 of the light emitting diode 400 to suppress permeation of moisture and external foreign materials. The encapsulation unit 600 may include a first encapsulation layer 610, a second encapsulation layer 620, and a third encapsulation layer 630 which are sequentially laminated, but the exemplary embodiments of the present disclosure are not limited thereto.

The first encapsulation layer 610 and the third encapsulation layer 630 of the encapsulating unit 600 may be formed of an inorganic material, such as silicon oxide (SiOx). The second encapsulation layer 620 of the encapsulation unit 600 may be formed of an organic material, such as acryl resin, epoxy resin, phenolic resin, polyamide resin, or polyimide resin, but the exemplary embodiments of the present disclosure are not limited thereto.

The dam 550 including the same material layer as the bank layer 510 and the same material layer as the spacer 520 may be disposed at an edge of the second encapsulation layer 620. The dam 550 may be formed by additionally laminating the first encapsulation layer 610 and the third encapsulation layer 630.

The dam 550 may suppress the second encapsulation layer 620 from flowing to the outside of the display panel 10 during the process of forming the encapsulation unit 600. The second encapsulation layer 620 is formed of an organic material and may be formed to have a large thickness to planarize a lower step formed in the second encapsulation layer 620. The second encapsulation layer 620 before being cured has a flowability so that a dam for blocking the flow of the second encapsulation layer 620 is necessary.

The dam 550 is formed by extending a part of the encapsulation unit 600 to perform a sealing function and protect the sub pixel PX from moisture entering into the display panel 10 from the side surface.

A plurality of dams may be formed to effectively suppress the flowing of the second encapsulation layer 620 to the outside.

A touch sensor 700 including a plurality of touch electrodes may be disposed on the encapsulation unit 600.

A touch buffer layer 705 may be disposed between the encapsulation unit 600 and the touch sensor 700. The touch buffer layer 705 suppresses the damage of the encapsulation unit 600 and may block an interference signal of a signal of the thin film transistor 300 which affects the touch sensor 700. The touch buffer layer 705 may facilitate the formation of the touch sensor 700 on the encapsulation unit 600 and improve the adhesive force of the touch sensor 700 and the encapsulation unit 600.

The touch buffer layer 705 includes an inorganic material such as silicon oxide (SIOx), silicon nitride (SiNx), or silicon oxy nitride (SiOxNy), and may be provided as a single layer or a plurality of layers.

A touch buffer layer 705 may be disposed between the encapsulation unit 600 and the touch sensor 700. The touch buffer layer 705 may be formed of an organic material and allows the touch sensor 700 to be easily formed on the encapsulation unit 600 and improve a fixing force of the touch sensor 700 to the encapsulation unit 600.

The touch sensor 700 may include a lower touch electrode 710, an upper touch electrode 730 which are a plurality of touch electrodes and a touch insulating film 720 which is disposed between the lower touch electrode 710 and the upper touch electrode 730 and on a part of the non-active area NA. The touch insulating film 720 may be formed of an inorganic material, for example, a silicon nitride layer (SiNx), a silicon oxy nitride layer (SiON), a silicon oxide layer (SiOx), a titanium oxide layer (TiOx), or an aluminum oxide layer (AlOx).

The lower touch electrode 710 may be a bridge electrode which connects upper touch electrodes 730 which are adjacent to each other. The lower touch electrode 710 and the upper touch electrode 730 may use one of a material, such as titanium (Ti), aluminum (Al), molybdenum (Mo), or copper (Cu), or use a mixture thereof. For example, the lower touch electrode 710 and the upper touch electrode 730 may be configured by laminating a titanium layer (Ti)-an aluminum layer (Al)-a titanium layer (Ti) or laminating a molybdenum layer (Mo)-an aluminum layer (Al)-a molybdenum layer (Mo).

The touch insulating film 720 may be disposed on the lower touch electrode 710. The touch insulating film 720 may be disposed on top surfaces of the lower touch electrode 710 and/or the touch buffer layer 705 while being in contact therewith. The touch insulating film 720 may be disposed to extend to the non-active area NA.

The upper touch electrode 730 may be formed on the touch insulating film 720. The upper touch electrode 730 includes a driving electrode and a sensing electrode, and may sense a touch by means of a capacitance change between the driving electrode (or driving electrode line) and the sensing electrode (or sensing electrode line). The upper touch electrode 730 may use the same material as the lower touch electrode 710.

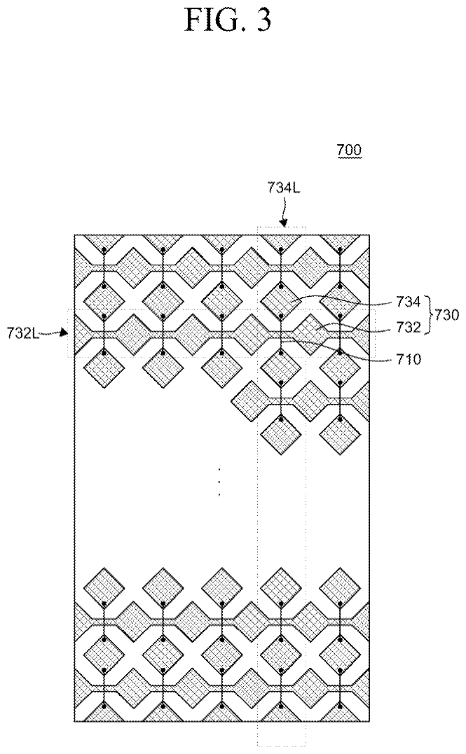

FIG. 3 is a view illustrating a touch sensor according to an exemplary aspect of the present disclosure.

FIG. 3 illustrates a mutual-capacitance based touch sensing method, but the present disclosure is not limited thereto and may be applied to a self-capacitance based touch sensing method.

Referring to FIG. 3, the touch sensor 700 may include the lower touch electrode 710 which is a bridge electrode and the upper touch electrode 730 disposed on the lower touch electrode 710. The upper touch electrode 730 may refer to a touch electrode and include a driving electrode 732 (or a transmission electrode) to which a driving signal is applied, and a sensing electrode 734 (or a reception electrode) which senses a sensing signal and forms a capacitance with the driving electrode 732.

A touch insulating film 720 may be formed between the lower touch electrode 710 and the upper touch electrode 730, and the lower touch electrode 710 forms a contact hole in the touch insulating film 720 to be connected to the driving electrode 732 or the sensing electrode 734.

Among the driving electrodes 732 of the touch sensor 700, driving electrodes 732 disposed in the same row (or the same column) are electrically connected to each other by an integration method (or connected by the bridge electrode) to form one driving electrode line 732L.

Among the sensing electrodes 734, sensing electrodes 734 disposed in the same column (or the same row) are electrically connected to each other by the bridge electrode 710 (or by integration method) to form one sensing electrode line 734L.

In the case of the mutual-capacitance manner, the touch circuit applies a driving signal to one or more driving electrode lines 732L, and receives a sensing signal from one or more sensing electrode lines 734L. The touch circuit may detect a capacitance change between a driving touch line and a sensing touch line according to the presence of the contact, such as a finger or a pen, based on the received sensing signal to detect the presence of touch and/or a touch coordinate.

To transmit a driving signal and a sensing signal, each of the plurality of driving electrode lines 732L and the plurality of sensing electrode lines 734L may be electrically connected to a touch driving circuit through one or more touch lines.

As the touch sensor 700 according to the exemplary aspect of the present disclosure, a mesh type touch sensor 700 having an opening area may be applied. The present disclosure is not limited thereto and as the touch sensor 700, a non-mesh type may be also applied. The non-mesh type touch sensor 700 may be a plate shape electrode metal which does not have an opening area. In this case, the touch sensor 700 may be a transparent electrode.

A plurality of opening areas is formed in the mesh-type upper touch electrode 730 and/or lower touch electrode 710 and each of the plurality of opening areas may correspond to emission areas of the plurality of sub pixels PX.

Referring to FIG. 2, a touch protection layer 740 which protects the touch sensor 700 may be disposed on the touch sensor 700.

The touch protection layer 740 may be formed on the entire area of the display panel 10. The touch protection layer 740 may have a flat upper surface in the active area AA, and have a shape corresponding to a side end profile of the encapsulation unit 600 in the non-active area NA. The touch protection layer 740 may be disposed to cover the encapsulation unit 600 and the touch sensor 700.

The touch protection layer 440 may be formed of a photo-curable organic material which is any one of acrylic, polyimide, or siloxane-based material.

The touch protection layer 440 covers the entire display panel 10 so that the touch protection layer 440 may be removed from a partial area of the pad portion PAD in which the data driver 50 and the circuit board 30 are mounted.

A partial area of the touch protection layer 440 is also removed from an end area of the non-active area NA of the display substrate 110 to form a plurality of partition walls 745. The plurality of partition walls 745 may be formed to suppress a material which configures the cover layer 800 from flowing to the outside of the display panel 10 during the process of forming the cover layer 800 disposed on the touch protection layer 440, and serve as dams which block the flow of the cover layer 800 before being cured.

The plurality of partition walls 745 is disposed in the non-active area NA and may be configured by the same material as the touch protection layer 440.

To remove the touch protection layer 440 in a partial area of the non-active area NA, a photolithographic process using a mask may be used. For example, after fully applying an organic material, such as acrylic or polyimide-based material, as a material for forming the touch protection layer 440, on the display substrate 110, exposure and development are used using a mask to remove the touch protection layer 440. The touch protection layer 440 uses an organic material having a photo-sensitive property, such as an acrylic or polyimide-based material, and may be removed without performing an etching process.

Alternatively, an organic material, such as acrylic or polyimide-based material, may be applied as a material for forming the touch protection layer 440 on the display substrate 110. After fully applying and curing the organic material, exposure, development, and etching processes are performed using a photo-sensitive material to remove the touch protection layer 440.

A cover layer 800 may be disposed on the touch protection layer 740 and the plurality of partition walls 745. The cover layer 800 may serve to further planarize an area which is not partially planarized by the touch protection layer 740.

In the non-active area NA, the touch protection layer 740 is formed to be curved along a side profile of an end portion of the encapsulation unit 600 so that the light emitted from the side surface of the display panel 10 may be emitted to be curved by the encapsulation unit 600 and the touch protection layer 740.

Accordingly, the image displayed on the side surface of the display panel 10 may be displayed to be curved and the cover layer 800 may be disposed on the touch protection layer 740 to compensate for a side surface image of the display panel 10.

The cover layer 800 is additionally disposed in an inclined portion of the side surface of the touch protection layer 740 to planarize a part of the side surface of the touch protection layer 740 so that the image which is displayed to be curved on the side surface of the display panel 10 may be corrected.

The cover layer 800 may have a substantially flat top surface and a first thickness h1 in a part of the active area AA and the non-active area NA and may be formed to have a second thickness h2 larger than the first thickness h1 in the inclined portion of the side surface of the touch protection layer 70.

The cover layer 800 may be in direct contact with a side surface and a top surface of the touch protection layer 740.

The cover layer 800 may be formed to include an organic material having a refractive index higher than that of the touch protection layer 740, for example, having a high refractive index. Accordingly, the refractive index of the cover layer 800 may be larger than the refractive index of the touch protection layer 740 and light which is emitted to be curved from the side surface of the display panel 10 is additionally corrected to implement an image without having waviness.

For example, when a refractive index of the touch protection layer 740 is in the range of approximately 1.3 to 1.6, a refractive index of the cover layer 800 may be in the range of approximately 1.65 to 1.85.

When the touch protection layer 740 uses an acrylic or polyimide resin, the cover layer 800 may include polydiarylsiloxane, methyltrimethoxysilane, or tetramethoxysilane.

The cover layer 800 may include dispersed particles to achieve high refractive index. For example, in the cover layer 800, metal oxide particles, such as zinc oxide (ZnOx), titanium oxide (TiO₂), zirconium oxide (ZrO₂), or barium titan oxide (BaTiO₃) may be dispersed.

When the cover layer 800 forms a part of the inclined side surface of the touch protection layer 740 to be flat, the cover layer 800 may include an organic material such as an acrylic or polyimide-based material, which is the same material as the touch protection layer 740.

The cover layer 800 may be formed by applying and curing an organic material using an inkjet 810.

The cover layer 800 before being cured is a fluid material having a predetermined viscosity and downwardly flows in the inclined area of the side surface of the display panel 10 so that it may be difficult to form a flat surface.

Accordingly, to suppress the downward flowing of the organic material and flowing of the organic material to the outside of the display panel 10, the plurality of partition walls 745 may be formed with the touch protection layer 740.

When the plurality of partition walls 745 formed of organic materials is disposed on the touch insulating film 720, the touch buffer layer 705, the third encapsulation layer 630, or the first encapsulation layer 610 formed of an inorganic material, the resulting adhesive force may be low due to different physical properties of the organic material and the inorganic material. When the plurality of partition walls 745 has a low adhesive force, the plurality of partition walls 745 may be tilted or collapsed by the flow of the cover layer 800 before being cured, and may fall off or separate.

To suppress the plurality of partition walls 745 from being tilted or collapsed due to the flow of the cover layer 800, the plurality of partition walls 745 formed of organic materials may be formed on an organic material or a component for fixing the plurality of partition walls 745 may be added.

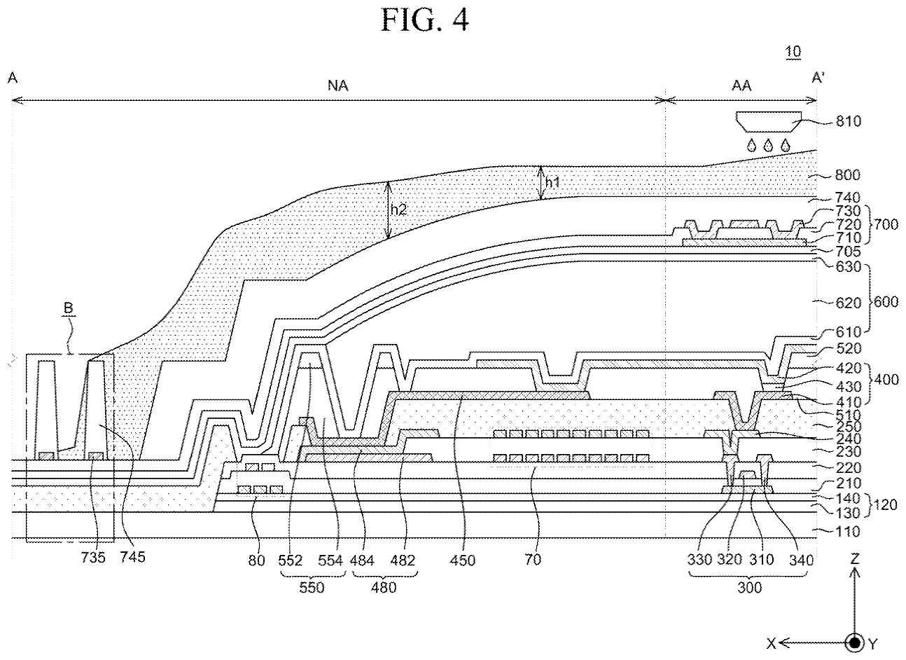

FIG. 4 is a cross-sectional view taken along the line A-A′ of FIG. 1A according to another exemplary aspect of the present disclosure.

Referring to FIG. 4, the plurality of partition walls 745 disposed in an end area of the non-active area NA of the display panel 100 is formed on the touch insulating film 720, so that a low adhesive force (or a fixing force) may be generated. To supplement the low adhesive force of the plurality of partition walls 745, a partition wall fixing unit 735 may be formed below the plurality of partition walls 745.

The plurality of partition walls 745 and the partition wall fixing unit 735 are not limited to be forming on the touch insulating film 720. The plurality of partition walls 745 and the partition wall fixing unit 735 may be formed on the touch insulating film 720, the touch buffer layer 705, the third encapsulation layer 630, the first encapsulation layer 610, the bank layer 510, the second planarization layer 250, or the first planarization layer 230.

The partition wall fixing unit 735 may be formed of the same material as the upper touch electrode 730. The partition wall fixing unit 735 may use one of a material, such as titanium (Ti), aluminum (Al), molybdenum (Mo), or copper (Cu), or use a mixture thereof.

In another example, the partition wall fixing unit 735, alone or in combination with the plurality of partition walls 745, may operate as a crack stopper to prevent crack(s) from forming in the display panel 10. Such crack stopper may have an organic pattern formed of organic material including, but not limited to, polyimide (PI), polyamide, an acrylic resin, benzocyclobutene, hexamethyldisiloxane (HMDSO), or phenol resin, and have a similar physical property configured by acrylic, polyimide based, or siloxane-based material to have a high adhesive force.

The partition wall fixing unit 735 may be disposed to be in contact with a bottom surface of the plurality of partition walls 745. The plurality of partition walls 745 may be formed to be larger than the partition wall fixing unit 735 and disposed to cover a top surface and a side surface of the partition wall fixing unit 735.

The plurality of partition walls 745 is in contact with the side surface and the top surface of the partition wall fixing unit 735 so that a contact area is larger than an area when the plurality of partition wall fixing units 735 is in direct contact onto the touch insulating film 720 to improve the adhesive force. A part of the plurality of partition walls 745 which is not in contact with the partition wall fixing unit 735 may be in contact with the touch insulating film 720 to be fixed.

The partition wall fixing unit 735 may increase a surface area by forming a surface roughness to be large. When the surface roughness of the partition wall fixing unit 735 is increased, a contact area between the plurality of partition walls 745 and the partition wall fixing unit 735 is further increased so that the adhesive force may be further increased.

When the touch insulating film 720 is not disposed at an end area of the display panel 100 in the non-active area NA, the partition wall fixing unit 735 may be formed by the lower touch electrode 710. The plurality of partition walls 745 may be fixed by the partition wall fixing unit 735 and the touch buffer layer 705.

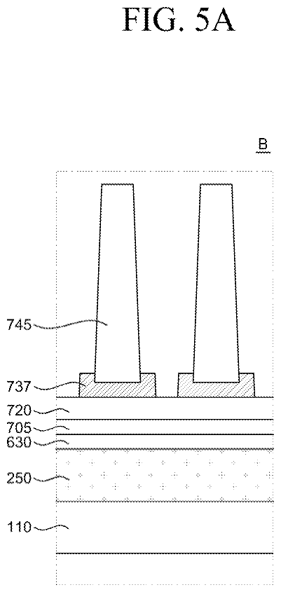

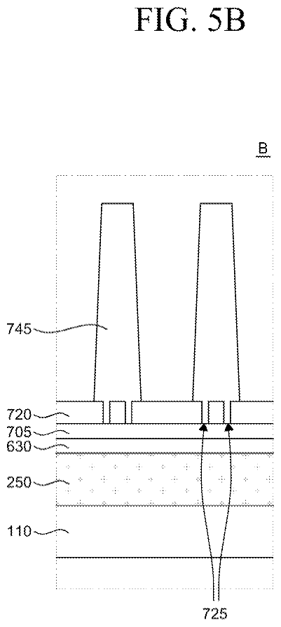

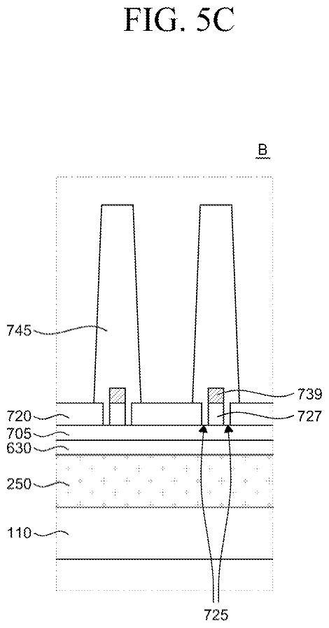

FIGS. 5A to 5C are views illustrating another example of a plurality of partition walls in a region B of FIG. 4.

Referring to FIG. 5A, a partition wall fixing unit 737 may be formed to be larger than a width of the plurality of partition walls 745. The partition wall fixing unit 737 may be formed in a U shape to be in contact with a bottom surface of the plurality of partition walls 745 and be in contact with a part of the side surface of the plurality of partition walls 745.

The plurality of partition walls 745 is disposed on the partition wall fixing unit 735 so that a height of the plurality of partition walls 745 may be increased. The height of the plurality of partition walls 745 is high so that the effect of blocking the flow of the cover layer 800 may be improved. Further, the plurality of partition walls 745 may be additionally fixed by the side surface of the partition wall fixing unit 735 so that the adhesive force (or a fixing force) may also be improved.

The plurality of partition walls 745 and the partition wall fixing units 737 may be disposed on the touch insulating film 720, the touch buffer layer 705, the third encapsulation layer 630, the first encapsulation layer 610, the bank layer 510, the second planarization layer 250, or the first planarization layer 230.

FIG. 5B is another example of the plurality of partition walls.

Referring to FIG. 5B, the touch insulating film 720 is disposed to extend to the non-active area NA and the plurality of partition walls 745 may be disposed on the touch insulating film 720.

To increase the adhesive force of the plurality of partition walls 745 and the touch insulating film 720 disposed there below, a contact area of the plurality of partition walls 745 and the touch insulating film 720 may be increased. To this end, in a partial area of the touch insulating film 720 overlapping the plurality of partition walls 745, a plurality of opening areas 725 in which the touch insulating film 720 is not disposed may be included.

For example, in an area of the touch insulating film 720 overlapping the plurality of partition walls 745, when the touch insulating film 720 is partially removed with a predetermined area therebetween, the plurality of opening areas 725 in which the touch insulating film 720 is not disposed may be formed in the overlapping area with the plurality of partition walls 745.

When the plurality of partition walls 745 is formed on the touch insulating film 720 including the plurality of opening areas 725, a lower end of the plurality of partition walls 745 is filled in a removed area of the touch insulating film 720 to improve the adhesive force of the plurality of partition walls 745 and the touch insulating film 720. That is, the contact area of the plurality of partition walls 745 and the touch insulating film 720 is increased to improve the adhesive force.

The plurality of opening areas 725 is not limited to being formed on the touch insulating film 720, but may be formed on the touch insulating film 720, the touch buffer layer 705, the third encapsulation layer 630, the first encapsulation layer 610, the bank layer 510, the second planarization layer 250, or the first planarization layer 230.

Accordingly, the plurality of partition walls 745 may be formed on the touch insulating film 720, the touch buffer layer 705, the third encapsulation layer 630, the first encapsulation layer 610, the bank layer 510, the second planarization layer 250, or the first planarization layer 230.

FIG. 5C is another exemplary aspect of the plurality of partition walls.

Referring to FIG. 5C, in a structure in which the plurality of opening areas 725 is formed in the touch insulating film 720 overlapping the plurality of partition walls 745, a first touch insulating film unit 727 which is a part of the touch insulating film 720 is disposed between the plurality of opening areas 725. Further, a partition wall fixing unit 739 may be disposed on the first insulating film unit.

The plurality of partition walls 745 is disposed in the plurality of opening areas 725 so that the contact area of the touch insulating film 720 and the plurality of partition walls 745 is increased to improve the adhesive force. The partition wall fixing unit 739 is additionally disposed below the plurality of partition walls 745 to increase the adhesive force (or a fixing force) by which the plurality of partition walls 745 is fixed.

The plurality of opening areas 725 is not limited to being formed on the touch insulating film 720, but may be formed on the touch insulating film 720, the touch buffer layer 705, the third encapsulation layer 630, the first encapsulation layer 610, the bank layer 510, the second planarization layer 250, or the first planarization layer 230.

Accordingly, the plurality of partition walls 745 and the partition wall fixing unit 739 may be formed on the touch insulating film 720, the touch buffer layer 705, the third encapsulation layer 630, the first encapsulation layer 610, the bank layer 510, the second planarization layer 250, or the first planarization layer 230.

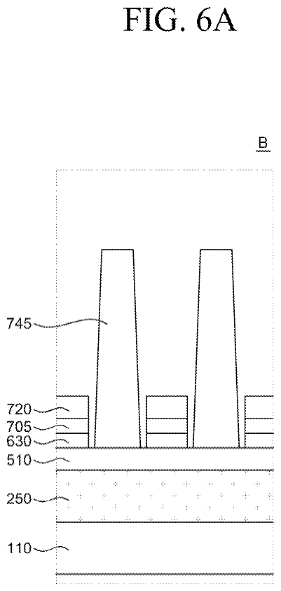

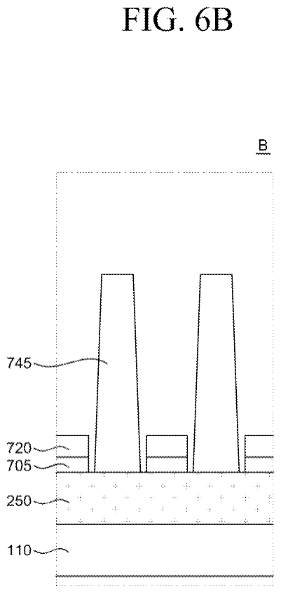

FIGS. 6A and 6B are views illustrating another exemplary aspect of a plurality of partition walls of a region B of FIG. 4.

Referring to FIG. 6A, to improve the adhesive force of the plurality of partition walls 745, the plurality of partition walls 745 configured by an organic material is in contact with a bank layer 510 which is configured by an organic material to be fixed.

The bank layer 510 may be disposed on the same layer as the emission layer 430 and the bank layer 510 may be disposed to extend to the non-active area NA.

When the plurality of partition walls 745 which is configured by an organic material is in contact with the touch insulating film 720, the touch buffer layer 705, the third encapsulation layer 630, or the first encapsulation layer 610 which is configured by an inorganic material to be fixed, the adhesive force may be formed to be low due to different physical properties of the organic material and the inorganic material.

The bank layer 510 may be configured by an organic material, such as polyimide (PI), polyamide, an acrylic resin, benzocyclobutene, hexamethyldisiloxane (HMDSO), or phenol resin, and have a similar physical property to the plurality of partition walls 745 configured by acrylic, polyimide based, or siloxane-based material to have a high adhesive force. Materials of the bank layer 510 and the plurality of partition walls 745 are not limited thereto.

To bring the plurality of partition walls 745 to be in contact with the bank layer 510, one or more of the touch insulating film 720, the touch buffer layer 705, the third encapsulation layer 630, and the first encapsulation layer 610 which may be disposed between the plurality of partition walls 745 and the bank layer 510 may be removed.

One or more of the touch insulating film 720, the touch buffer layer 705, the third encapsulation layer 630, and the first encapsulation layer 610 may be disposed to extend to the non-active area NA and an area to be removed may be an area overlapping the plurality of partition walls 745 or the entire non-active area NA. For example, in the area overlapping the plurality of partition walls 745, the touch insulating film 720 may not be disposed.

When one or more of the touch insulating film 720, the touch buffer layer 705, the third encapsulation layer 630, and the first encapsulation layer 610 are removed from the area overlapping the plurality of partition walls 745, a side surface in which one or more of the touch insulating film 720, the touch buffer layer 705, the third encapsulation layer 630, and the first encapsulation layer 610 are laminated is located on the side surface of the plurality of partition walls 745. Therefore, the plurality of partition walls 745 is additionally suppressed from being detached to be separated.

Referring to FIG. 6B, to improve the adhesive force of the plurality of partition walls 745, the plurality of partition walls 745 configured by an organic material may be in contact with the second planarization layer 250 or the first planarization layer 230 which is configured by an organic material to be fixed.

The first planarization layer 230 and the second planarization layer 250 may be disposed between the thin film transistor 300 and the light emitting diode 400.

The second planarization layer 250 or the first planarization layer 230 may be configured by an organic material such as polyimide (PI), polyamide, or acrylic resin. A material which configures the second planarization layer 250 or the first planarization layer 230 is not limited thereto.

To bring the plurality of partition walls 745 to be in contact with the second planarization layer 250, one or more of the touch insulating film 720, the touch buffer layer 705, the third encapsulation layer 630, and the first encapsulation layer 610 which may be disposed between the plurality of partition walls 745 and the second planarization layer 250 may be removed. An area to be removed may be the entire area overlapping the plurality of partition walls 745 or the entire non-active area NA.

To bring the plurality of partition walls 745 to be in contact with the first planarization layer 230, one or more of the touch insulating film 720, the touch buffer layer 705, the third encapsulation layer 630, the first encapsulation layer 610, and the second planarization layer 250 which may be disposed between the plurality of partition walls 745 and the first planarization layer 250 may be removed. An area to be removed may be the entire area overlapping the plurality of partition walls 745 or the entire non-active area NA.

When one or more of the touch insulating film 720, the touch buffer layer 705, the third encapsulation layer 630, the first encapsulation layer 610, and the second planarization layer 250 are removed from the area overlapping the plurality of partition walls 745, a side surface in which one or more of the touch insulating film 720, the touch buffer layer 705, the third encapsulation layer 630, the first encapsulation layer 610, and the second planarization layer 250 are laminated is located on the side surface of the plurality of partition walls 745. Therefore, the plurality of partition walls 745 is additionally suppressed from being detached to be separated.

Other layers than a layer configured by an organic material may not be formed below an area where the plurality of partition walls 745 is disposed. For example, one or more of the bank layer 510, the first planarization layer 230, and the second planarization layer 250 are laminated to be configured below an area where the plurality of partition walls 745 is disposed.

The exemplary embodiments of the present disclosure may also be described as follows:

According to an aspect of the present disclosure, a display apparatus may comprising a display substrate including an active area in which an image is displayed and a non-active area which encloses the active area, a thin film transistor which is disposed on the display substrate and includes a semiconductor layer, a gate electrode, a source electrode, and a drain electrode, a light emitting diode which is disposed on the thin film transistor of the active area and includes a first electrode, an emission layer, and a second electrode, an encapsulation unit disposed on the light emitting diode, a touch sensor which is disposed on the encapsulation unit and includes a plurality of touch electrodes, a touch protection layer which is disposed to cover the touch sensor, a plurality of partition walls which is disposed in the non-active area and is configured with the same material as the touch protection layer, and a cover layer disposed on the touch protection layer and the plurality of partition walls.

The display apparatus may further comprise a partition wall fixing unit which is configured with the same material as the plurality of touch electrodes and is in contact with bottom surfaces of the plurality of partition walls.

The plurality of partition walls may be disposed to cover a top surface and a side surface of the partition wall fixing unit.

The partition wall fixing unit may be in contact with bottom surfaces and a part of side surfaces of the plurality of partition walls.

The plurality of touch electrodes may include a lower touch electrode and an upper touch electrode, the touch sensor further includes a touch insulating film disposed between the lower touch electrode and the upper touch electrode, the touch insulating film extends to the non-active area, and a plurality of opening areas in which the touch insulating film is not disposed in an area overlapping the plurality of partition walls is included.

A first touch insulating film portion may be disposed between the plurality of opening areas and a partition wall fixing unit is disposed on the first touch insulating film portion.

The plurality of touch electrodes may include a lower touch electrode and an upper touch electrode, the touch sensor may further include a touch insulating film disposed between the lower touch electrode and the upper touch electrode, the touch insulating film extends to the non-active area, and the touch insulating film may be not disposed in an area overlapping the plurality of partition walls.

The display apparatus may further comprise a bank layer disposed on the same layer as the emission layer, the bank layer extends to the non-active area, and the plurality of partition walls may be in contact with the bank layer.

The display apparatus may further comprise a first planarization layer and a second planarization layer disposed between the thin film transistor and the light emitting diode, the first planarization layer and the second planarization layer extend to the non-active area, and the plurality of partition walls may be in contact with one of the first planarization layer and the second planarization layer.

A refractive index of the cover layer may be higher than a refractive index of the touch protection layer.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protection scope of the present disclosure should be interpreted based on the following appended claims and it should be appreciated that all technical spirits included within a range equivalent thereto are included in the protection scope of the present disclosure.

Claim language or other language reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

What is claimed is:

1. A display apparatus, comprising:
a display substrate including an active area configured to display an image and a non-active area enclosing the active area;
a thin film transistor on the display substrate that includes a semiconductor layer, a gate electrode, a source electrode, and a drain electrode;
a light emitting diode on the thin film transistor of the active area that includes a first electrode, an emission layer, and a second electrode;
an encapsulation unit on the light emitting diode;
a touch sensor on the encapsulation unit that includes a plurality of touch electrodes;
a touch protection layer configured to cover the touch sensor;
a dam configured to prevent at least a part of the encapsulation unit from flowing to the outside of the display substrate in the non-active area;
a crack detection unit configured to detect at least one crack in the display apparatus; and
a data line configured to supply common voltage to the light emitting diode.

2. The display apparatus according to claim 1, further comprising:
an organic layer in the non-active area configured to prevent the at least one crack in the display apparatus.

3. The display apparatus according to claim 1, wherein the crack detection unit is on the same layer as the gate electrode

4. The display apparatus according to claim 1, wherein the data line is on the same layer as at least one of the source electrode, the drain electrode or a connection electrode which connects a thin film transistor and a light emitting diode.

5. The display apparatus according to claim 2, wherein the crack detection unit is disposed between the dam and the organic layer.

6. The display apparatus according to claim 1, wherein the dam is disposed between the crack detection unit and the data line.

7. The display apparatus according to claim 1, further comprising:
a connection line; and
a common line disposed at an end area of the connection line and including a first common line and a second common line,
wherein the data line is configured to supply the common voltage to the connection line.

8. The display apparatus according to claim 7, wherein the first common line, the second common line, and the connection line are connected to each other at the lower part of the dam.

9. The display apparatus according to claim 7 at least one of the first common line, the second common line, or the connection line are in the same layer as the data line.

10. The display apparatus according to claim 2,
wherein the organic layer configured with the same material as the touch protection layer.

11. The display apparatus according to claim 7,
wherein the connection line is disposed to overlap at least a part of the data line.

12. The display apparatus according to claim 7, further comprising:
a hole disposed between the bank and the dam in the non-active area,
wherein the connection line and at least a part of the encapsulation unit are connected through the hole.

13. The display apparatus of claim 10, further comprising:
a partition wall fixing unit configured with the same material as the plurality of touch electrodes and configured to be in contact with bottom surfaces of the organic layer.

14. The display apparatus according to claim 13, wherein the organic layer is configured to cover a top surface and a side surface of the partition wall fixing unit.

15. The display apparatus according to claim 13, wherein the partition wall fixing unit is configured to be in contact with bottom surfaces and a part of side surfaces of the organic layer.

16. The display apparatus according to claim 10, further comprising:
a cover layer on the touch protection layer and the organic layer.

17. The display apparatus according to claim 16, wherein a refractive index of the cover layer is higher than a refractive index of the touch protection layer.

18. The display apparatus according to claim 1, wherein
the plurality of touch electrodes includes a lower touch electrode and an upper touch electrode,
the touch sensor further includes a touch insulating film between the lower touch electrode and the upper touch electrode,
the touch insulating film extends to the non-active area, and
a plurality of opening areas in which the touch insulating film is not disposed in an area overlapping the organic layer is included.

19. The display apparatus according to claim 18, wherein a first touch insulating film portion is between the plurality of opening areas and a partition wall fixing unit is on the first touch insulating film portion.

20. The display apparatus according to claim 1, wherein
the plurality of touch electrodes includes a lower touch electrode and an upper touch electrode,
the touch sensor further includes a touch insulating film between the lower touch electrode and the upper touch electrode,
the touch insulating film extends to the non-active area, and
the touch insulating film is not disposed in an area overlapping the organic layer.

21. The display apparatus according to claim 20, further comprising:
a bank layer on the same layer as the emission layer,
wherein the bank layer extends to the non-active area, and the organic layer is in contact with the bank layer.

22. The display apparatus according to claim 20, further comprising:
a first planarization layer and a second planarization layer between the thin film transistor and the light emitting diode,
wherein the first planarization layer and the second planarization layer extend to the non-active area, and the organic layer is in contact with one of the first planarization layer and the second planarization layer.

23. A display apparatus, comprising:
a display substrate including an active area configured to display an image and a non-active area enclosing the active area;
an organic layer in the non-active area configured to prevent a crack in the display apparatus; and
a crack detection unit configured to detect at least one crack in the display apparatus.

24. The display apparatus of claim 23, further comprising:
a light emitting diode in the active area;
an encapsulation layer on the light emitting diode; and
a dam configured to prevent at least a part of the encapsulation layer unit from flowing to the outside of the display substrate in the non-active area.
